(19) United States
(12) Patent Application Publication
(10) Pub. No.: US 2007/0161208 A1
(43) Pub. Date: Jul. 12, 2007

(54) SEMICONDUCTOR DEVICE AND FABRICATION METHOD THEREOF

(75) Inventor: Toshifumi Onizuka, Kumamoto (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/614,913

(22) Filed: Dec. 21, 2006

(30) Foreign Application Priority Data
Dec. 28, 2005 (JP) 2005-378748

(51) Int. Cl. H01L 21/76

(52) U.S. Cl. 438/435; 257/E21.546

(57) ABSTRACT

To prevent cracks in an insulator buried in a trench and fill the insulator completely in a place to be filled up. A process comprises: forming a trench 1a extending to an embedded insulation film 3 at a determined position on a first silicon substrate 1 of an SOI substrate 10; forming a first BPSG film 6 on the first silicon substrate 1 including the trench 1a not to fill in the trench 1a completely; forming an NSG film 7 on the first BPSG film 6, and forming a second BPSG film 8 on the NSG film 7. Each film forming step is performed in the same CVD furnace by a CVD method and a process changeover from one step to next is completed by changing a condition of gas species supplied into the CVD furnace.

### FIELD OF THE INVENTION

This invention relates to a semiconductor device having an element separation region of a trench being buried with an insulator formed on a semiconductor substrate and a manufacturing method thereof, and particularly relates to a semiconductor device having an insulator without any voids or cracks and a manufacturing method thereof.

### BACKGROUND OF THE INVENTION

An element isolation structure to insulate elements formed on a semiconductor substrate has been developed from a LOCOS structure to form an element isolation region by thermal oxidation into STI (Shallow Trench Isolation) structure to form an element isolation region buried with an insulator (insulation film) in a trench formed on a semiconductor substrate, in connection with a progress of high integration of a semiconductor device or fining of semiconductor elements. In addition, an STI structure using a SOI (Silicon On Insulator) substrate having an embedded insulator between silicon layers is employed recently as a semiconductor substrate instead of a silicon wafer itself in connection with an improvement of capacity of a semiconductor device. For such a STI structure it is necessary to fill up a trench with an insulator without voids and to flatten a concavity formed on a surface over the trench after filling up the insulator.

In Patent Document 1, a conventional fabrication method of a semiconductor device having a STI structure is disclosed as follows (see Patent Document 1). After formation of a trench 105 to a depth of an embedded insulation film 103 at a determined place of a first silicon substrate 101 on an SOI substrate 110, an NSG (Non-doped Silicate Glass) film 106 is formed all over the substrate 101 and the trench 105 is filled with the NSG film 106 completely (see FIG. 5A). Then a BPSG (Boron-Phosphor Silicate Glass) film 107 is formed on the NSG film 106 (see FIG. 5B) and the BPSG film 107 is heat-treated into flat surface (see FIG. 5C). After that the BPSG film 107 and the NSG film 106 are etched back up to a predetermined thickness to provide a flat surface (see FIG. 5D) (See Patent Document 1.).

[Patent Document 1]

Japanese Patent Kokai Publication No. JP-P2002-100672A

[Patent Document 2]

Japanese Patent Kokai Publication No. JP-P2000-200831A

The entire disclosure of Patent Documents 1 and 2 are incorporated herein by reference thereto.

### SUMMARY OF THE DISCLOSURE

According to the fabrication method disclosed in the Patent Document 1, the NSG film 106 for elements separation should be formed thick enough to fill the trench 105 surely. According to our investigation, however, it has turned out that a poor property of crack-resistance of the NSG film 106 causes cracks in the film and increases particles distributed in a furnace, therefore it is apprehended that an insulator cannot be filled completely in a place to be filled up. Besides that, the BPSG film 107, which is different from the NSG film 106 and has thermal fluidity, is formed to make the surface of the NSG film 106 flat in the fabrication method disclosed in Patent Document 1, however, because a heat treatment process or an etch back process is performed under the nitrogen atmosphere between the NSG film formation stage and the BPSG film formation stage, it is necessary to use furnaces of different specifications for each stages and to perform additional steps such as replacement to a nitrogen gas, re-airing, wafer transport, vacuuming, waiting for temperature stabilization, and so on other than the film formation steps (see FIG. 6). Even in case to use the same furnace for the NSG film formation, heat treatment and BPSG film formation step, a change of process conditions such as temperature, vacuum, flow rate, etc. is necessary for the BPSG film formation step after the heat treatment so as to perform additional step such as vacuuming, replacement to a nitrogen gas, waiting for temperature stabilization, etc. at the heat treatment after the NSG film formation step. Therefore, total sequential process time is rather long according to the fabrication method disclosed in Patent Document 1.

There is one conventional fabrication method of semiconductor device having an STI structure by forming a trench on a surface of a semiconductor substrate and depositing an insulation film of decomposition material of a TEOS (Tetra Ethyl Ortho Silicate) gas inside the trench. The method comprises a first growth process to grow a first TEOSNSG (Tetra Ethyl Ortho Silicate Non-doped Silicate Glass) film by gas phase thermal decomposition of the TEOS gas and a second growth step to grow a second TEOSNSG film by surface thermal decomposition of the TEOS gas at the surface of the semiconductor substrate as a filling process of an insulator (see Patent Document 2). However, it is also apprehended in this case that the TEOSNSG films (the first TEOSNSG film and the second TEOSNSG film), with a poor property of crack-resistance, tend to crack because an insulation film buried in the trench is TEOSNSG film only and the insulator cannot be filled completely in a place to be filled up.

A main problem to be solved by the present invention is to prevent cracks in an insulator buried in a trench and completely fill-in a place to be filled up with the insulator.

According to an aspect of the present invention, there is provided a fabrication method of a semiconductor device having an element separation region of a trench being buried with an insulator formed on a semiconductor substrate. The method comprises: a step of forming a trench at a determined position on the semiconductor substrate, a step of forming a first BPSG film on the semiconductor substrate including the trench not to fill in the trench completely, a step of forming an NSG film on the first BPSG film, and a step of forming a second BPSG film on the NSG film.

According to a second aspect, the method comprises: making a surface of the second BPSG film flat by heat treatment after formation of the BPSG film.

According to a third aspect, the method comprises: etching back the surface of the second BPSG film, or the second BPSG film and the NSG film, or the second BPSG film and the NSG film and the first BPSG film, up to a determined thickness to make a flat surface.

According to a fourth aspect, each of steps: forming of the first BPSG film, forming of the NSG film, and forming of the second BPSG film is performed in the same CVD furnace by a CVD method; and

a step change from one steps to next is executed by changing a condition of gas species sequentially supplied into the CVD furnace.

According to a fifth aspect, the gas species supplied into the CVD furnace for the forming the first BPSG film are tetra ethyl ortho silicate, phosphine, trimethyl borate and oxygen;

the gas species supplied into the CVD furnace for the forming the NSG film is tetra ethyl ortho silicate; and

the gas species supplied into the CVD furnace for the forming the second BPSG film are tetra ethyl ortho silicate, phosphine, trimethyl borate and oxygen.

According to a sixth aspect, the NSG film is formed with a thickness thinner than that of the first BPSG film in the forming the NSG film.

According to a seventh aspect, the semiconductor substrate is an SOI substrate having an embedded insulation film interposed between semiconductor layers; and

the trench is formed at a depth reaching the embedded insulation film at a determined place of the semiconductor layer on one side of the SOI substrate in the forming the trench.

According to an eighth aspect, there is provided a semiconductor device comprising:

a trench formed at a determined position on a semiconductor substrate;

a first BPSG film formed on the semiconductor substrate including the trench so as not to fill in the trench completely;

an NSG film formed on the first BPSG film; and

a second BPSG film formed on the NSG film, wherein the first BPSG film and the NSG film form an element separation region buried in the trench.

According to a ninth aspect, the semiconductor device comprises a co-existing region of the first BPSG film and the NSG film around a boundary between the first BPSG film and the NSG film.

According to a tenth aspect, the semiconductor device further comprises a co-existing region of the NSG film and the second BPSG film around a boundary between the NSG film and the second BPSG film.

According to an eleventh aspect, the second BPSG film has a flat surface produced by heat treatment after formation of the second BPSG film followed by etching.

According to a twelfth aspect, the device has an etched back flat surface resulting from etching back any one of the second BPSG film, or the second BPSG film and the NSG film, on the second BPSG film and the NSG film and the first BPSG film, up to a determined thickness.

The meritorious effects of the present invention are summarized as follows.

According to the present invention (various aspects 1 to 12), a crack-resistance property of an insulator for the use of element separation is improved and generation of particles in a CVD furnace can be suppressed. And the total required time for all sequential steps is shortened. That is, three layers of insulation films can be formed in a single CVD furnace and, therefore, steps of the entire process such as wafer transport, vacuuming in the CVD furnace, waiting for temperature stabilization, re-airing into CVD furnace and so on can be eliminated between consecutive film formation stages, respectively. In addition, the present invention can prevent formation of voids in the trench so that an improved flatness of the surface can be achieved.

### BRIEF DESCRIPTION OF THE DRAWINGS

FIGS. 1A, 1B and 1C show partial cross-sectional views of a first step illustrating a fabrication method of a semiconductor device in accordance with example 1 of the present invention.

FIGS. 2A, 2B and 2C show partial cross-sectional views of a second step illustrating a fabrication method of a semiconductor device in accordance with example 1 of the present invention.

FIGS. 3A, 3B and 3C show partial cross-sectional views of a third step illustrating a fabrication method of a semiconductor device in accordance with example 1 of the present invention.

FIG. 4 is a sequential chart of a fabrication method to form a first BPSG film, an NSG film and a second BPSG film in accordance with example 1 of the present invention.

FIGS. 5A, 5B, 5C and 5D illustrate a partial cross-sectional view of a process of a conventional fabrication method of a semiconductor device as a related art.

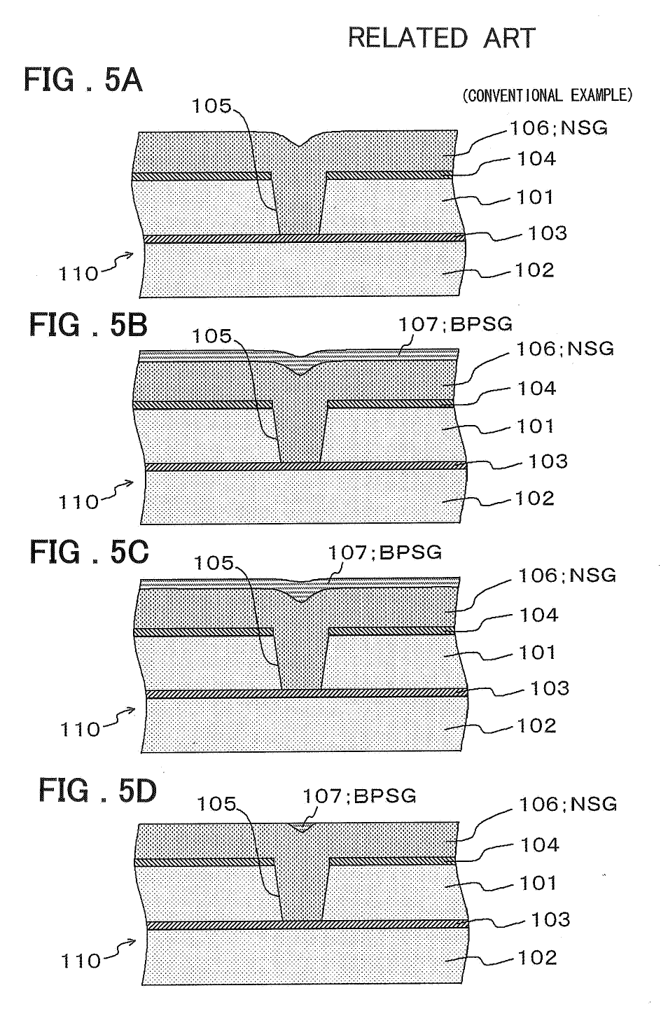

FIG. 6 is a sequential chart of a conventional fabrication method of a semiconductor device to form an NSG film and a BPSG film, as summarized by the present inventor.

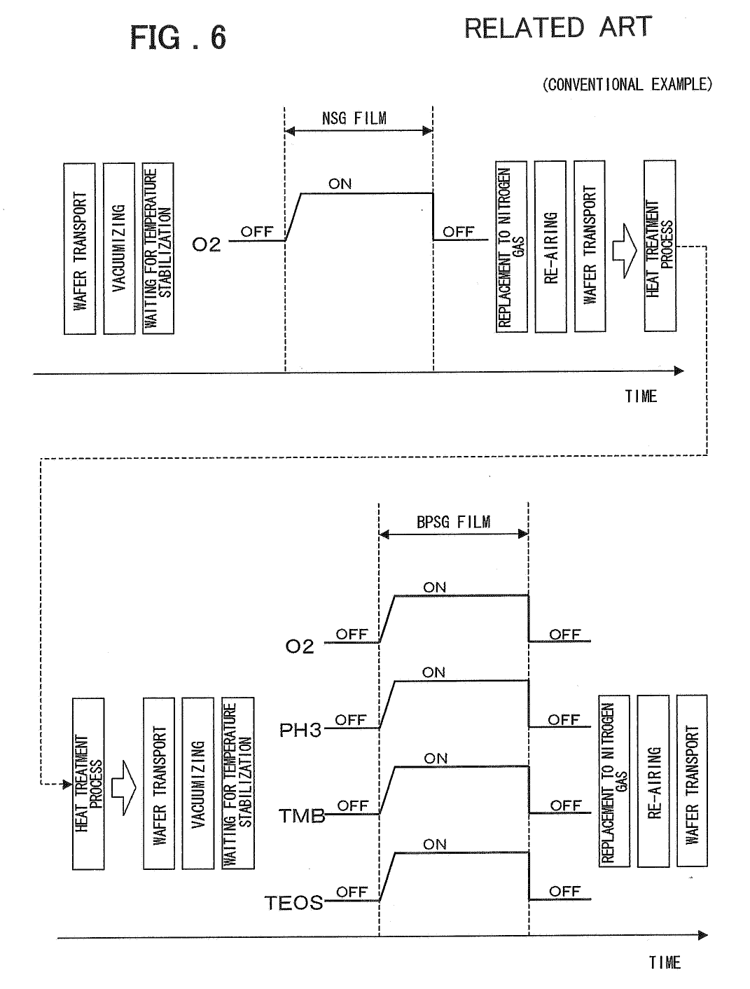

### PREFERRED MODES OF THE INVENTION

### EXAMPLE 1

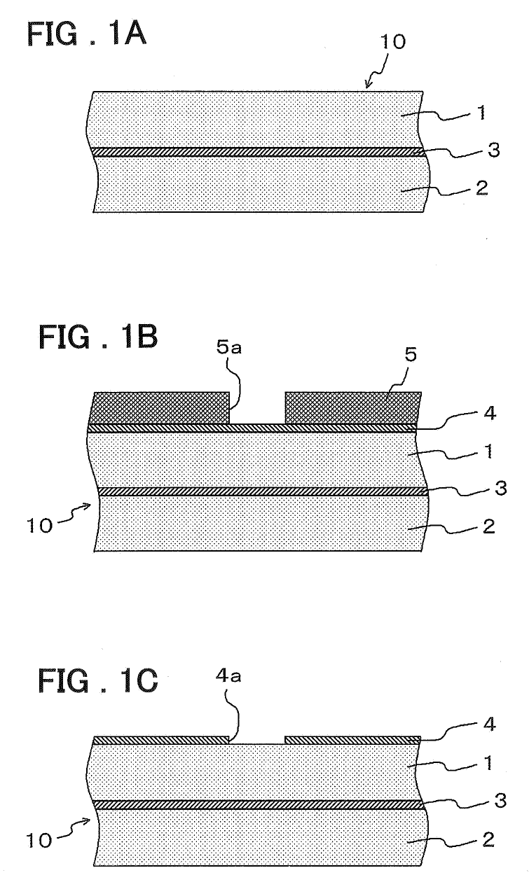

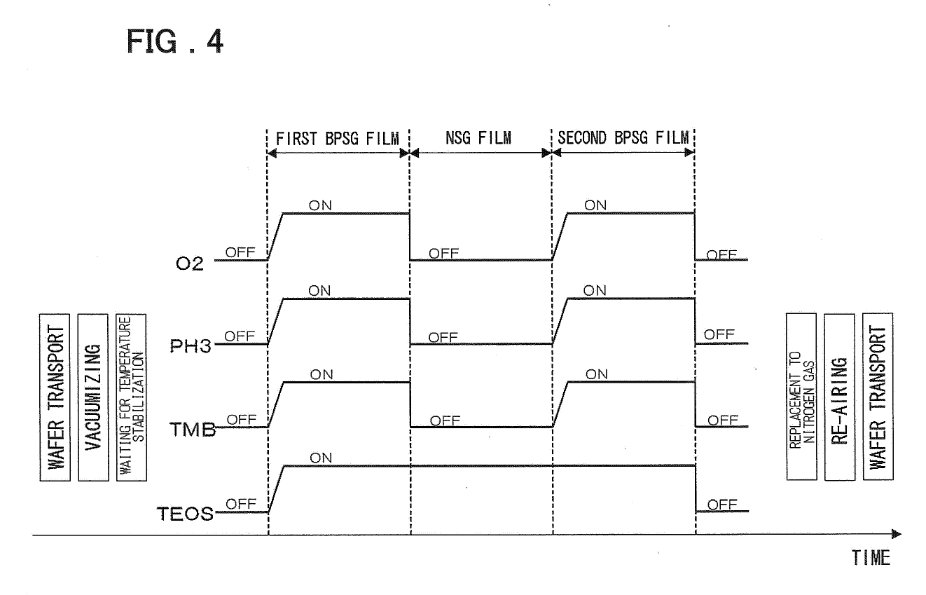

A semiconductor device in accordance with example 1 of the present invention is described in detail with reference to the figures. FIGS. 1A to 3C illustrate partial cross-sectional views of a fabrication method of a semiconductor device in accordance with example 1 of the present invention. FIG. 4 is a sequential chart of a fabrication method to form a first BPSG film, an NSG film and a second BPSG film in accordance with example 1 of the present invention.

At first a SOI (Silicon on Insulator) substrate 10 (wafer) containing an embedded insulation film 3, interposed between a first silicon substrate 1 and a second silicon substrate 2 is prepared (see FIG. 1A). To make the substrate 10, a backside of the first silicon substrate 1 is oxidized into the embedded insulation film 3, and the second silicon substrate 2 is laminated onto the surface of the embedded insulation film 3. Then the surface of the first silicon substrate 1 is polished to a flat surface to provide a main surface of the SOI substrate 10. The thickness of the first silicon substrate 1 is 3 to 7 μm, for example. The thickness of the second silicon substrate 2 is 500 to 800 μm, for example. A silicon oxide film, for example, is used as the embedded insulation film 3 and the thickness of the film is 0.5 to 2.5 μm, for example. In the figures, the thickness of the films provides no concrete ratio, as is apparent from the above disclosure.

Next, the surface of the first silicon substrate 1 is heat-treated and formed into silicon oxide film 4, and a photo resist 5 is coated on the silicon oxide film 4. An opening 5a over an element separation region is formed by removing the photo resist 5 on the element separation region selectively by photolithography technique (see FIG. 1B).

After formation of an opening 4a by etching of the silicon oxide film 4 using the photo resist 5 as a mask, the photo resist 5 is removed (see FIG. 1C).

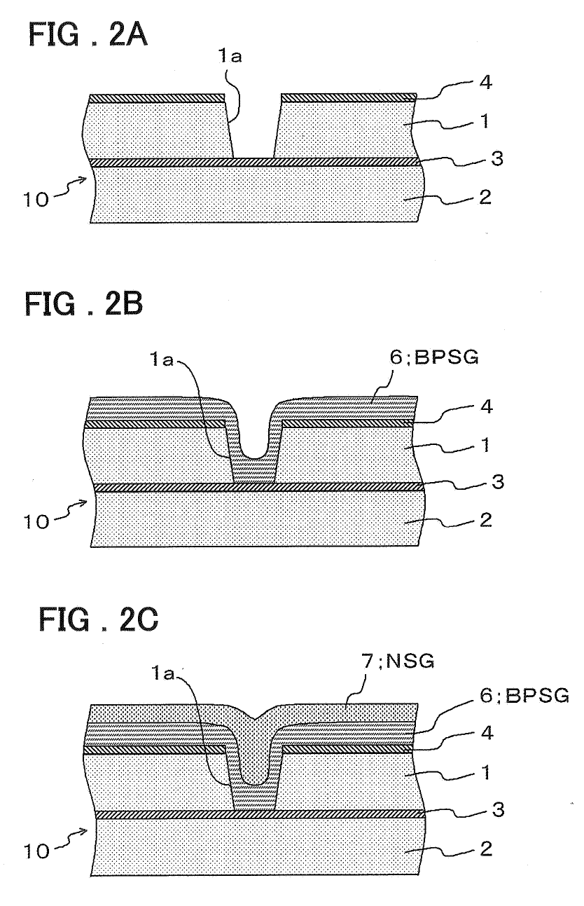

Next the first silicon substrate 1 is selectively etched down to reach the embedded insulation film 3 using the silicon oxide film 4 as a mask and then a trench 1a for element separation is formed (see FIG. 2A).

Then the SOI substrate 10 (wafer), the trench 1a is formed on it, is transported into a CVD (chemical Vapor Deposition) furnace (not shown) and vacuuming in the CVD furnace and temperature stabilizing waiting is performed to prepare a formation of an insulation film. At this step no gas species (TEOS, PH3, TMB and O2, for example) is supplied in the CVD furnace (see FIG. 4) and the conditions of the furnace are set to a determined level of vacuum (0.7 to 1.05 torr, for example) and a determined range of temperature (600 to 700° C., for example).

Where, TEOS is tetra ethyl ortho silicate (Si(C₂H₅O)₄), PH3 is phosphine (PH₃), TMB is trimethyl borate (B(CH₃O)₃) and O2 is oxygen (O₂).

As for the gas species, TEOS can be substituted by silane (SiH₄), PH3 can be substituted by trimethyl phosphite (P(CH₃O)₃), TMB can be substituted by triethyl borate (B(C₂H₅O)₃) or diborane (B₂H₆), and O2 can be substituted by ozone (O₃). The conditions such as pressure, temperature and so on are determined according to a selected combination of the gas species. A combination of gas species of TEOS, PH3, TMB and O2 is used, by way of example, in the description of following processes.

Next, the gas species of TEOS, PH3, TMB and O2 is supplied in the CVD furnace and the first BPSG (Boron-Phosphor Silicate Glass) film 6 is formed so as not to fill up the trench 1a completely by thermal decomposition (including gas phase thermal deposition and substrate surface thermal decomposition, the same hereafter) of the gas species (see FIG. 2B). A gas flow rate of each gas species to form the first BPSG film 6 is, for example, TEOS; 300 ml/min., PH3; 820 ml/min., TMB; 30 ml/min. and O2; 100 ml/min., respectively (see FIG. 4). And the thickness of the first BPSG film 6 formed in this process requires an appropriate thickness for a base of the NSG film 7 (500 to 800 nm, for example). A temperature and vacuum in the CVD furnace at this process can be tuned within a condition of preparation step (0.7 to 1.05 torr and 600 to 700° C., for example). The reason to use the first BPSG film 6 as a base of the NSG (Non-Doped Silicate Glass) film 7 is that the first BPSG film 6 has thermal fluidity (at a temperature range to be applied in the subsequent heat treating) and good property of crack-resistance.

Next, the NSG film 7 is formed on the first BPSG film 6 by thermal decomposition of TEOS gas by stopping the PH3, TMB and O2 gases and flowing TEOS gas only in the CVD furnace (see FIG. 2C). At this step, only the conditions (flow rates of gas species) are changed and the CVD furnace is the same as that of the step of forming the first BPSG film 6. Stopping the PH3, TMB and O2 gases is enough to change the conditions (see FIG. 4). And no heat treatment or etch back is performed at a time between the first BPSG film 6 forming step and the NSG film 7 forming step. The gas flow rates for the step of forming NSG film 7 are set at: for example, TEOS; 180 ml/min., PH3; 0 ml/min., TMB; 0 ml/min. and O2; 0 ml/min., respectively. The thickness of the NSG film 7 formed in this step should be thinner than that of the first BPSG film 6 and be appropriate in thickness to inhibit generation of cracks and particles, and to prevent formation of voids (400 to 600 nm, for example). The trench 1a is not necessarily filled up completely by the NSG film 7. And also a set temperature and set vacuum in the CVD furnace for this step can be tuned within a condition of preparation step (0.7 to 1.05 torr and 600 to 700° C., for example). There is a co-existing region of the first BPSG film 6 and the NSG film 7 around the boundary of the first BPSG film 6 and the NSG film 7 because when forming the NSG film the concentrations of remaining PH3, TMB and O2 gases are gradually decreased. The reason to introduce the NSG film 7 between the first BPSG film 6 and the second BPSG film 8 is to make the NSG film 7 thin. That is, as the thickness of the NSG film 7 increases, the crack-resistance property decreases and the NSG film 7 tends to generate cracks, accompanied by increased generation of particles in the CVD furnace. Therefore it can reduce generation of the cracks and particles by thinning the thickness of the NSG film 7.

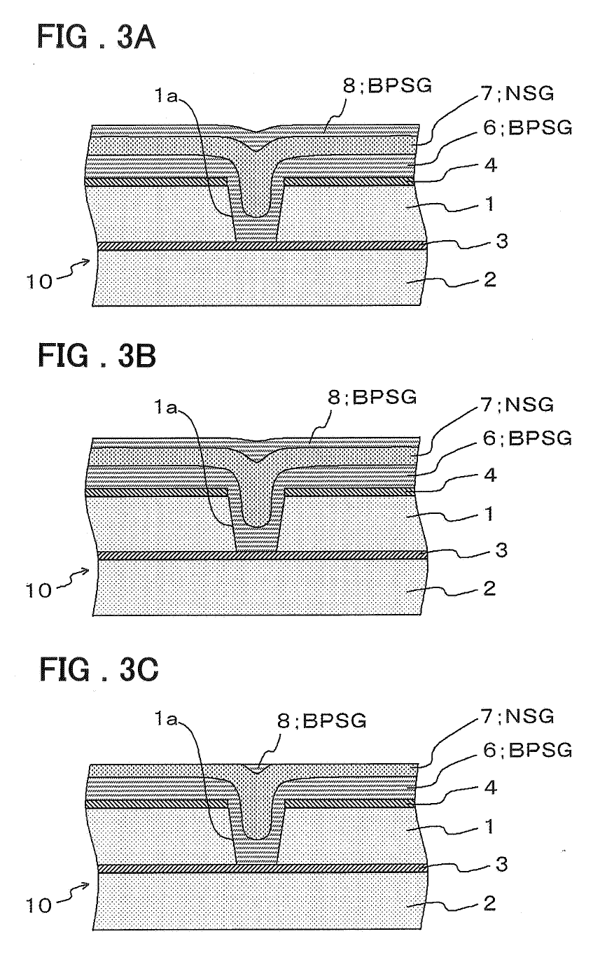

After that the PH3, TMB and O2 gas species are supplied again into the CVD furnace in which the TEOS gas is still kept flowing and the second BPSG film 8 is formed on the NSG film 7 by thermal decomposition of the gas species (see FIG. 3A). At this step, again only the conditions (flow rates of gas species) are changed and the CVD furnace is not changed compared to the steps of forming the first BPSG film 6 and the NSG film 7. The sequential change of the conditions besides in that the PH3, TMB and O2 gas species are supplied again with the TEOS gas being kept flowing (see FIG. 4). And no heat treatment or etch back is performed at a time between the NSG film 7 forming step and the second BPSG film 8 forming step. A gas flow rate of each gas species to form the second BPSG film 8 is, for example, TEOS; 300 ml/min., PH3; 820 ml/min., TMB; 30 ml/min. and O2; 100 ml/min., respectively. And the thickness of the second BPSG film 8 formed in this step requires (and should be sufficient to provide) an appropriate thickness to make the surface flat by heat treatment (200 to 300 nm, for example). And also a set temperature and set vacuum in the CVD furnace for this step can be tuned within a condition of preparation step (0.7 to 1.05 torr and 600 to 700° C., for example). There is a co-existing region of the NSG film 7 and the second BPSG film 8 around the boundary (interface) of the NSG film 7 and the second BPSG film 8, because when forming the second BPSG film 8 the concentrations of PH3, TMB and O2 gases are gradually increased. The reason to form the second BPSG film 8 on the NSG film 7 is that the surface of the second BPSG film 8 can be made flat by heat treatment because the BPSG film has thermal fluidity (at a temperature range for later heat treatment). After formation of the second BPSG film 8, the gas species to form the second BPSG film 8 remained in the furnace is replaced by nitrogen gas, then re-aired and the wafer is transported to a furnace for heat treatment (see FIG. 4).

Next, the wafer is heat-treated at a determined temperature (850° C., for example) during a determined time (20 min., for example) and the surface of the second BPSG film 8 is fluidized and becomes flat (see FIG. 3B). At this step, a small, smooth concavity remains on the surface.

Finally, one or more films of the second BPSG film 8, the NSG film 7, the first BPSG film 6 and the silicon oxide film 4 are etched back from the side of the second BPSG film 8 up to the thickness required at a succeeding step. For instance, the wafer is etched back up to reach the silicon oxide film 4 when the first BPSG film 6 is not needed on the silicon oxide film 4 at a succeeding step. If the silicon oxide film 4 is not required either, the wafer will be etched back up to reach the surface of the first silicon substrate 1.

According to example 1, by using the first BPSG film 6 as a base of the NSG film 7, the thickness of the NSG film 7 can be thin so that the crack-resistance property of the insulator (first BPSG film 6, NSG film 7 and second BPSG film 8) in the trench 1a is improved and the generation of particles can be suppressed. Besides that, a good covering property of the NSG film 7 enables the insulator in the trench 1a to suppress generation of voids. In addition, the thermal fluidity of the second BPSG film 8 can improve the flatness of the surface.

And three isolation films (first BPSG film 6, NSG film 7 and second BPSG film 8) can be formed in a single CVD furnace and a heat treatment or an etch back step between the successive formation steps of each insulation film is not necessary so that all of the steps such as wafer transport, vacuuming in the CVD furnace, temperature stabilization waiting, re-airing in the CVD furnace, etc. can be eliminated and a lead time can be shortened significantly. Because multiple insulation films can be formed without taking wafers out of the CVD furnace merely by changing conditions of gas species in the CVD furnace sequentially.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A fabrication method of a semiconductor device having an element separation region of a trench being buried with an insulator formed on a semiconductor substrate, comprising:
forming a trench at a determined position on a semiconductor substrate;
forming a first BPSG film on said semiconductor substrate including said trench so as not to fill in said trench completely;
forming an NSG film on said first BPSG film; and
forming a second BPSG film on said NSG film.

2. The fabrication method of a semiconductor device as defined in claim 1, further comprising: making a surface of said second BPSG film flat by heat treatment after formation of the BPSG film.

3. The fabrication method of a semiconductor device as defined in claim 1, comprising: etching back said surface of said second BPSG film, or said second BPSG film and said NSG film, or said second BPSG film and said NSG film and said first BPSG film, up to a determined thickness to make a flat surface.

4. The fabrication method of a semiconductor device as defined in claim 1, wherein:
each of steps: forming of said first BPSG film, forming of said NSG film, and forming of said second BPSG film is performed in the same CVD furnace by a CVD method; and
a step change from one step to next is executed by changing a condition of gas species sequentially supplied into said CVD furnace.

5. The fabrication method of a semiconductor device as defined in claim 4, wherein:
said gas species supplied into said CVD furnace for said forming said first BPSG film are tetra ethyl ortho silicate, phosphine, trimethyl borate and oxygen;
said gas species supplied into said CVD furnace for said forming said NSG film is tetra ethyl ortho silicate; and
said gas species supplied into said CVD furnace for said forming said second BPSG film are tetra ethyl ortho silicate, phosphine, trimethyl borate and oxygen.

6. The fabrication method of a semiconductor device as defined in claim 1, wherein said NSG film is formed with a thickness thinner than that of said first BPSG film in said forming said NSG film.

7. The fabrication method of a semiconductor device as defined in claim 1, wherein:
said semiconductor substrate is an SOI substrate having an embedded insulation film interposed between semiconductor layers; and
said trench is formed at a depth reaching said embedded insulation film at a determined place of said semiconductor layer on one side of said SOI substrate in said forming said trench.

8. A semiconductor device comprising:
a trench formed at a determined position on a semiconductor substrate;
a first BPSG film formed on said semiconductor substrate including said trench so as not to fill in said trench completely;
an NSG film formed on said first BPSG film; and
a second BPSG film formed on said NSG film, wherein said first BPSG film and said NSG film form an element separation region buried in said trench.

9. The semiconductor device as defined in claim 8, comprising a co-existing region of said first BPSG film and said NSG film around a boundary between said first BPSG film and said NSG film.

10. The semiconductor device as defined in claim 8, further comprising;
a co-existing region of said NSG film and said second BPSG film around a boundary between the NSG film and the second BPSG film.

11. The semiconductor device as defined in claim 8, wherein said second BPSG film has a flat surface produced by heat treatment after formation of the second BPSG film.

12. The semiconductor device as defined in claim 8, wherein said device has an etched back flat surface resulting from etching back any one of said second BPSG film, or said second BPSG film and said NSG film, or said second BPSG film and said NSG film and said first BPSG film, up to a determined thickness.
